(19) United States
(12) Patent Application Publication
(10) Pub. No.: US 2009/0225524 A1
(43) Pub. Date: Sep. 10, 2009

(54) Hollowed Printed Circuit Board Having Via Hole And Method For Forming Via Hole In Hollowed Printed Circuit Board

(76) Inventors: Chin-Kuan Liu, Taoyuan (TW); Chun-Hong Liu, Taoyuan (TW)

Correspondence Address: LIN & ASSOCIATES INTELLECTUAL PROPERTY, INC., P.O. BOX 2339, SARATOGA, CA, 95070-0339, US

(21) Appl. No.: 12/043,961

(22) Filed: Mar. 7, 2008

(51) Int. Cl. H05K 7/00; H01K 3/10

(52) U.S. Cl. 361/760; 29/852

(57) ABSTRACT

A method for forming a via hole in a hollowed PCB, which has a hollow portion and at least one insulating layer, includes the steps of: providing a lining pad on a first surface of the insulating layer that is adjacent to the hollow portion; drilling the via hole in the insulating layer from a second surface of the insulating layer that is opposite to the first surface of the insulating layer. In such a way, when the insulating layer is drilled to form the via hole, the insulating layer is supported by the lining pad, thereby preventing the defects, such as burrs, cracks, or pads, from occurring.

### BACKGROUND OF THE INVENTION

1. Field of the Invention

The present invention relates generally to a reinforced hollowed printed circuit board (PCB) or a reinforced hollowed chip carrier having a via hole and a method for forming a via hole in a hollowed PCB. The present invention provides a lining pad in the PCB or the chip carrier, so as to avoid defects which are often generated when forming the via hole, such as burrs, cracks, or pads.

2. The Prior Arts

PCBs or chip carriers are often classified into a rigid type and a flexible type. To manufacture a PCB or a chip carrier, circuit patterns are formed on a copper foil by steps including pre-processing, providing photo-resist layer, exposing, developing, etching, and removing the photo-resist layer. Thereafter, a black oxide treatment or a brown oxide treatment is conducted to roughen a copper surface so as to improve the adhesion to a substrate. Then, the copper layer and the substrate are laminated together by the application of heat and pressure. Double-layer or multi-layer PCB/chip carrier is formed by bonding together the single layers. Then, via holes are drilled and plated to connect circuit patterns from one layer to another layer(s).

However, some electronic devices, such as micro electro-mechanical system (MEMS), may include PCBs having hollow portions between layers. The hollow portion is a cavity which makes the layers of the PCB lack support during forming via holes. The layers of the PCB are likely to deform when drilling the via holes. Therefore, defects, such as burrs, cracks, or pads, are very likely to occur. The defects sometimes may damage and disable the product, e.g. piercing a component film of an audio hole which destroys the whole product. Further, forming the via hole not only is likely to cause the defects mentioned above in the insulating layers of the circuit board but also is likely to damage the copper foil layers, especially the solder pads, which causes malfunction of the product.

### SUMMARY OF THE INVENTION

A primary objective of the present invention is to provide a reinforced hollowed PCB having a via hole and a method for forming a via hole in a hollowed PCB. The present invention provides a reinforced PCB, so as to avoid defects, such as burrs, cracks, or pads, which are often generated during forming the via holes.

For achieving the foregoing objective, a method for forming a via hole in a hollowed PCB or a hollowed chip carrier according to the present invention includes the steps of: providing a plastic lining pad on a first surface of an insulating layer that is adjacent to a hollow portion; drilling a via hole in the insulating layer from a second surface of the insulating layer that is opposite to the first surface. In such a way, when the insulating layer is drilled to form the via hole, the insulating layer is supported by the lining pad, thereby preventing the defects from occurring.

### BRIEF DESCRIPTION OF THE DRAWINGS

The present invention will be apparent to those skilled in the art by reading the following detailed description of preferred embodiments thereof, with reference to the attached drawings, in which:

FIGS. 1A and 1B are schematic diagrams illustrating a via hole being formed in a hollowed printed circuit board or a hollowed chip carrier according to a first embodiment of the present invention; and

FIG. 2 is a schematic diagram illustrating a via hole being formed in a hollowed printed circuit board or a hollowed chip carrier according to a second embodiment of the present invention.

### DETAILED DESCRIPTION OF THE PREFERRED EMBODIMENT

A method for forming a via hole in a hollowed printed circuit board according to the present invention includes the steps of providing a lining pad in a hollowed PCB, and forming a via hole from a side of the hollowed PCB opposite to the lining pad. In such a way, the lining pad strengthens structure around the via hole and provides additional support to the formation of the via hole. Thus, the quality of the via hole or routing is improved, and defects, such as burrs, cracks, or pads, are prevented from occurring. In the following, more details are to be given for further illustrating the present invention.

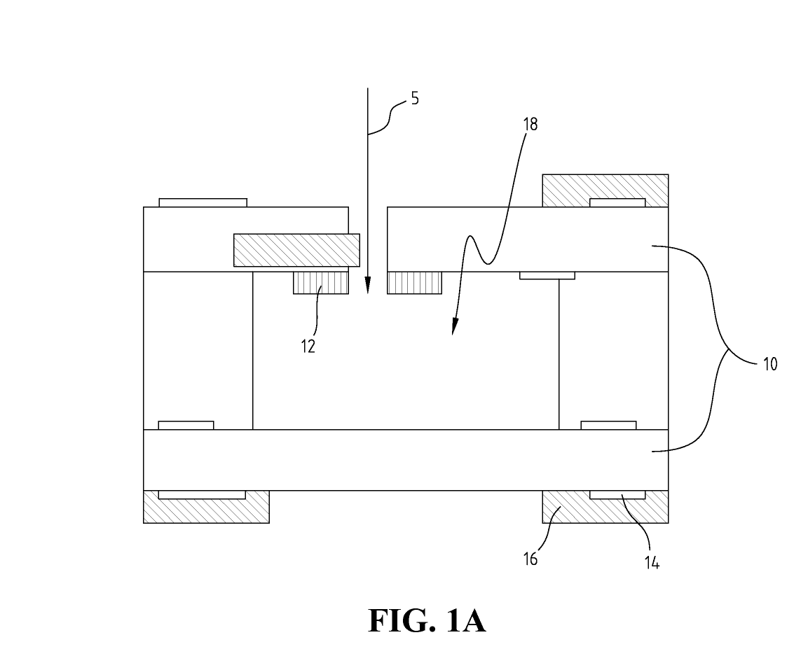

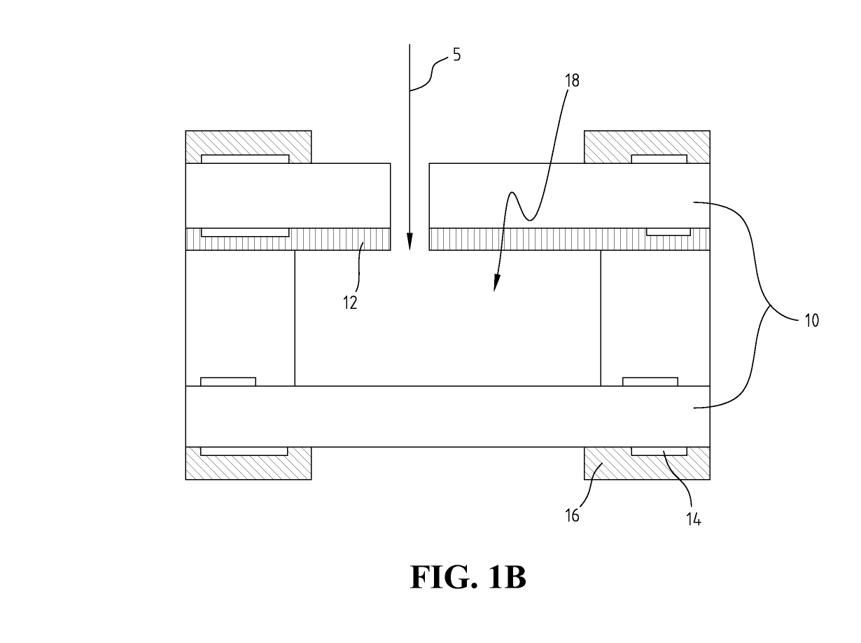

Referring to FIGS. 1A and 1B, a via hole is formed in a hollowed printed circuit board (PCB) or a hollowed chip carrier according to a first embodiment of the present invention. The PCB or the chip carrier includes at least one insulating layer 10, and a hollow portion 18. A circuit pattern 14 may be coated on the insulating layer 10 and a solder mask 16 is coated on the circuit pattern 14. The insulating layer 10 is made of a material selected from a group consisting of fiberglass-epoxy resin, polyimide, and epoxy resin.

In order to enhance the strength of PCB/chip carrier around the via hole, a lining pad 12 is provided on a first surface of the insulating layer that is adjacent to the hollow portion 18. The lining portion 12 is disposed at an region where the via hole is going to be formed as shown in FIG. 1A, or on the entire first surface of insulating layer 10 as shown in FIG. 1B. The lining pad 12 may be made of a plastic material or a material the same as that of the insulating layer 10. A via hole is formed from a second surface of the insulating layer 10, which is opposite to the first surface of the insulating layer 10, along a direction 5. The via hole can be a blind via hole or a through via hole. When the via hole is formed in the PCB or the chip carrier, the lining pad 12 reinforces a via hole forming area. Therefore, the lining pad 12 improves the quality of the via hole and routing.

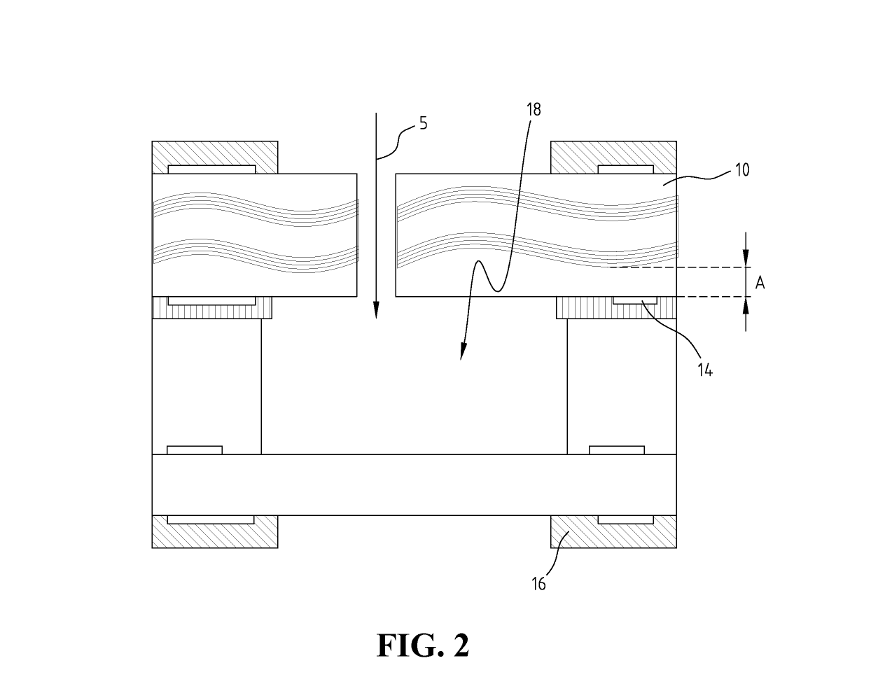

Referring to FIG. 2, a via hole is formed in a hollowed printed circuit board or a hollowed chip carrier according to a second embodiment of the present invention. The PCB or the chip carrier includes at least one insulating layer 10, and a hollow portion 18. A circuit pattern 14 may be coated on the insulating layer 10 and a solder mask 16 is coated on the circuit pattern 14.

The insulating layer 10 according to the second embodiment of the present invention is made of fiberglass-epoxy resin. In order to enhance the strength of the PCB or the chip carrier around the via hole, the fiberglass-epoxy resin is thickened. A lining pad A is a thickened portion of the fiberglass-epoxy resin, which is defined from a first surface of the fiberglass-epoxy resin that is adjacent to the hollow portion 18 to an inner fiberglass that is the closest to the first surface of the fiberglass-epoxy resin. An increased thickness of the fiberglass epoxy resin, which is a thickness of the lining pad A, is greater than 15 μm. A via hole is formed from a second surface of the insulating layer 10, which is opposite to the first surface of the fiberglass-epoxy resin, along a direction 5. The via hole can be a blind via hole or a through via hole.

Although the present invention has been described with reference to the preferred embodiments thereof, it is apparent to those skilled in the art that a variety of modifications and changes may be made without departing from the scope of the present invention which is intended to be defined by the appended claims.

What is claimed is:

1. A method for forming a via hole in one of a printed circuit board and a circuit carrier that has a hollow portion and at least one insulating layer, the method comprising the steps of:
providing a lining pad on a first surface of the insulating layer that is adjacent to the hollow portion; and
forming the via hole in the insulating layer from a second surface of the insulating layer that is opposite to the first surface of the insulating layer.

2. The method according to claim 1, wherein the lining pad is provided at an area where the via hole is formed.

3. The method according to claim 1, wherein the insulating layer is made of glass-epoxy resin and the lining pad is a thickened portion of the fiberglass-epoxy resin.

4. The method according to claim 3, wherein an increased thickness of the fiberglass-epoxy resin is greater than 15 μm.

5. The method according to claim 3, wherein the thickened portion of the fiberglass-epoxy resin is defined from a surface that is adjacent to the hollow portion to a glass fiber in the fiberglass-epoxy resin that is the closest to the surface thereof, the thickened portion of the fiberglass-epoxy resin has a thickness greater than 15 μm.

6. The method according to claim 1, wherein the insulating layer is made of a material selected from a group consisting of fiberglass-epoxy resin, polyimide, and epoxy resin.

7. The method according to claim 1, wherein the lining pad is made of one of a plastic material and a material the same as that of the insulating layer.

8. The method according to claim 1, wherein the via hole is one of a blind via hole and a through via hole.

9. A hollowed circuit board having a via hole, comprising
a hollow portion; and
at least one insulating layer;
wherein a lining pad is provided on a surface of the insulating layer that is adjacent to the hollow portion.

10. The hollowed circuit board according to claim 9, wherein the circuit board is one of a printed circuit board and a chip carrier.

11. The hollowed circuit board according to claim 9, wherein the lining pad is provided at an area where the via hole is formed.

12. The hollowed circuit board according to claim 9, wherein the insulating layer is made of glass-epoxy resin and the lining pad is a thickened portion of the fiberglass-epoxy resin.

13. The hollowed circuit board according to claim 12, wherein an increased thickness of the fiberglass-epoxy resin is greater than 15 μm.

14. The hollowed circuit board according to claim 12, wherein the thickened portion of the fiberglass-epoxy resin is defined from a surface that is adjacent to the hollow portion to a glass fiber in the fiberglass-epoxy resin that is the closest to the surface thereof; the thickened portion of the fiberglass-epoxy resin has a thickness greater than 15 μm.

15. The hollowed circuit board according to claim 9, wherein the insulating layer is made of a material selected from a group consisting of fiberglass-epoxy resin, polyimide, and epoxy resin.

16. The hollowed circuit board according to claim 9, wherein the lining pad is made of one of a plastic material and a material the same as that of the insulating layer.

17. The hollowed circuit board according to claim 9, wherein the via hole is one of a blind via hole and a through via hole.
